(19) United States
(12) Patent Application Publication
(10) Pub. No.: US 2013/0320896 A1
(43) Pub. Date: Dec. 5, 2013

(54) MODULAR INVERTER ARRANGEMENT

(71) Applicant: ABB Oy, Helsinki (FI)

(72) Inventors: Pertti SEVÄKIVI, Lepsama (FI); Teemu Heikkilä, Helsinki (FI)

(21) Appl. No.: 13/909,607

(22) Filed: Jun. 4, 2013

(30) Foreign Application Priority Data
Jun. 4, 2012 (EP) 12170647.7

(51) Int. Cl. H05K 7/20

(52) U.S. Cl. CPC H05K 7/2089
USPC 318/400.26; 363/123

(57) ABSTRACT

An arrangement for a modular inverter includes a number of power semiconductors and cooling elements, where the cooling elements are connected to the power semiconductors for cooling the power semiconductors. The power semiconductors and the cooling elements are disposed around a center axis of the arrangement in such a manner that they demark a channel around the center axis in which a cooling medium is able to flow in the direction of the center axis. The arrangement includes a first tube-shaped ring film capacitor around the center axis of the arrangement. The power semiconductors are arranged between the cooling elements and an inner surface of the first tube-shaped ring film capacitor.

### RELATED APPLICATION

This application claims priority under 35 U.S.C. §119 to European Patent Application No. 12170647.7 filed in Europe on Jun. 4, 2012, the entire content of which is hereby incorporated by reference in its entirety.

### FIELD

The present disclosure relates to a modular inverter arrangement.

### BACKGROUND INFORMATION

An inverter is an electrical device which enables generation of a voltage with a variable frequency. Inverters can be used in connection with motors for controlling them with a variable frequency or, correspondingly, when electrical power is transmitted back to the network, whereby the inverter generates a voltage with a frequency that corresponds to the frequency of the network. Such an inverter feeding the network is generally called a network inverter. An inverter can also be a part of a frequency converter used for controlling a motor or another load. A frequency converter can be formed of two converters, i.e. a rectifier and an inverter, between which there is a direct-voltage or direct-current intermediate circuit. The rectifier and the inverter can also be positioned physically separated from each other, and one rectifier can feed several inverters via a common intermediate circuit or, alternatively, several rectifiers can feed one inverter. An example of a rectifier is a diode bridge or a thyristor bridge. Frequency converters can also include one or more choke devices. Examples of such choke devices used in or in connection with frequency converters include an input choke connected to the input of the rectifier of the frequency converter, and an output choke connected to the output of the inverter of the frequency converter.

Known frequency converter structures include an input choke, an input bridge, a capacitor bank and an IGBT (Insulated-Gate Bipolar Transistor) module. The capacitor bank is usually a complicated set of multiple capacitors and it usually requires cooling. Up to protection class IP20 (Ingress Protection), mechanical devices are usually constructed with one blower, in which the main flow of cooling medium, such as air, is conveyed to the cooling element of the power semiconductors and to other objects by means of the kind of distribution they require. The cooling element is, as a rule, a one-part or a multi-part element, the parts being bunched together with support mechanics.

In protection class IP21 or in higher protection classes, the electronics space (what is called clean room) and the space for the cooling element (what is called dirty room) can be separated from each other for practical reasons. In order for both spaces to have the right amount of air, both spaces are generally provided with a blower of their own. The possible input choke is often positioned on the dirty side, either in a separate air space or in the space following the cooling element. Alternatively, the possible AC input choke can also be replaced by a DC choke connected to the intermediate circuit, but in this case, too, the mechanical position of the choke is in the same place. The possible structure-specific output choke is often positioned mechanically in the same place as the input choke. In some structures, the possible chokes are positioned completely outside the device, in which case they are, due to the cooling and their own support mechanism, larger in size than they would be if integrated.

Known inverter and frequency converter structures or, more generally, motor controller structures are problematic particularly with regard to arranging the cooling. Although the size of the cooling element or elements required has continuously been decreasing due to more accurate designing, smaller losses and physically smaller power semiconductors, the required amount of air (or amount of another cooling medium) relative to the outer dimensions of the device has even increased. Also, distribution of a sufficient amount of air is generally done by means of a large blower at a low blasting rate, taking into account the power, sound and service life of the blower. For this reason, the space required by the cooling is, relative to the size of the device, rather large in known techniques. This is further emphasized in IP21 or higher protection classes, for example.

### SUMMARY

An exemplary embodiment of the present disclosure provides an arrangement for a modular inverter. The exemplary arrangement includes a plurality of power semiconductors and cooling elements, where the cooling elements are connected to the power semiconductors for cooling the power semiconductors, and the cooling elements each respectively have cooling surfaces. The power semiconductors and the cooling elements are disposed around a center axis of the arrangement such that the power semiconductors and the cooling elements demark a channel around the center axis from at least three sides. The channel cooling surfaces of the cooling elements extend to the channel, and a cooling medium is able to flow in the direction of the center axis in the channel. The power semiconductors extend from connections between the power semiconductors and the cooling elements substantially away from the center axis. The exemplary arrangement also includes a first tube-shaped ring film capacitor disposed around the center axis of the arrangement. The power semiconductors are arranged between the cooling elements and an inner surface of the first ring film capacitor.

### BRIEF DESCRIPTION OF THE DRAWINGS

Additional refinements, advantages and features of the present disclosure are described in more detail below with reference to exemplary embodiments illustrated in the drawings, in which:

FIG. 1 shows an exemplary embodiment of an arrangement of an inverter unit, seen from above;

FIG. 2 shows an exemplary embodiment of an arrangement of a combination of an inverter unit and an inverter supply unit, seen from above; and

FIG. 3 shows an exemplary embodiment of an arrangement of a three-level inverter unit, seen from above.

### DETAILED DESCRIPTION

Exemplary embodiments of the present disclosure provide an apparatus which solves or at least alleviates the drawbacks noted above with respect to known techniques. An exemplary embodiment of the present disclosure provides an arrangement for a modular inverter. The exemplary arrangement includes a plurality of power semiconductors and cooling elements, where the cooling elements are connected to the power semiconductors for cooling the power semiconductors, and the cooling elements each respectively have cooling surfaces. The power semiconductors and the cooling elements are disposed around a center axis of the arrangement such that the power semiconductors and the cooling elements demark a channel around the center axis from at least three sides. The channel cooling surfaces of the cooling elements extend to the channel, and a cooling medium is able to flow in the direction of the center axis in the channel. The power semiconductors extend from connections between the power semiconductors and the cooling elements substantially away from the center axis. The exemplary arrangement also includes a first tube-shaped ring film capacitor disposed around the center axis of the arrangement. The power semiconductors are arranged between the cooling elements and an inner surface of the first ring film capacitor. An exemplary embodiment of the present disclosure also provides a modular inverter such as a motor controller, for example, which includes the above-described arrangement.

Exemplary embodiments of the present disclosure are based on the idea that power semiconductors and cooling elements associated with the power semiconductors are disposed around a center axis of the arrangement inside at least one tube-shaped ring film capacitor in such a manner that the cooling elements demark a channel around the center axis from at least three sides, to which channel cooling surfaces of the cooling elements extend and in which a cooling medium is able to flow in the direction of the center axis.

An advantage of the arrangement according to the present disclosure is that the structure of the arrangement provides a natural channel for the flow of the cooling medium, which enables controlled circulation of the cooling medium, such as air, for example, through the device because a tube shaped capacitor surrounds the power stages and the cooling elements. Owing to this, the cooling can be implemented efficiently while saving space at the same time. Further, the present disclosure allows the cooling to be implemented uniformly in different parts of the device. Furthermore, the solution according to the present disclosure enables a modular structure, which provides advantages for the production and maintenance of the device, for example.

The present disclosure can be applied in connection with various inverter solutions and is thus not restricted to be used in connection with any particular type of device. As an example, an inverter unit, a combination of an inverter unit and an inverter supply unit, and a three-level inverter unit are presented here as exemplary embodiments of the present disclosure. However, the presented disclosure should not be considered to be restricted to these three devices or a combination of them, as any person skilled in the art should understand. The types of the inverter feed, the load controlled by the inverter or the connections between them, such as the voltage level or the number of phases, is not relevant to the basic idea of the present disclosure either. Further, the internal or external electrical connections of the inverter in connection with which the present disclosure is applied are not relevant to the present disclosure, so the electrical connections are, for the sake of clarity, omitted from the drawings. The present disclosure is not confined to the examples shown in the drawings but can be applied to other types of inverter solutions as well.

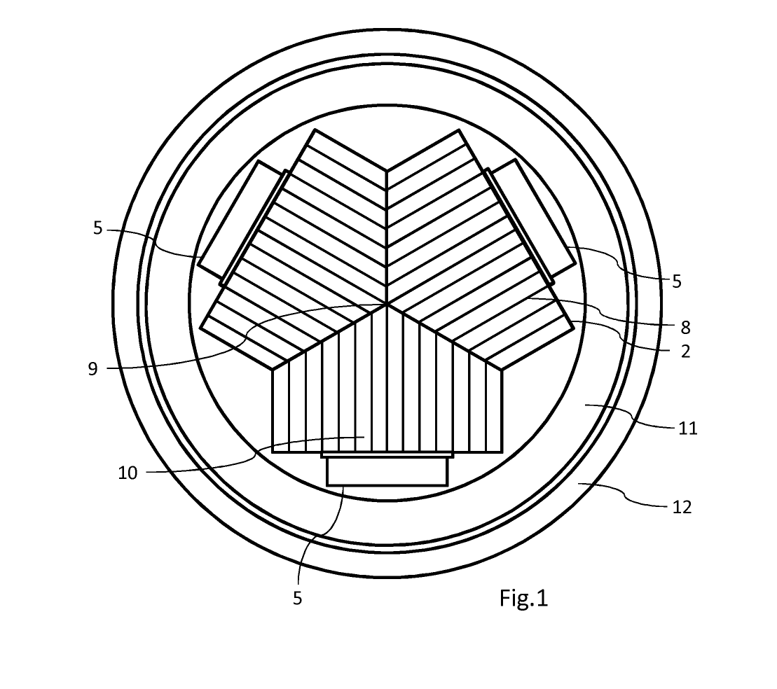

FIG. 1 shows a top view of an arrangement according to an exemplary embodiment of the present disclosure. The arrangement shown in FIG. 1 includes three power semiconductors 5, or three groups of power semiconductors, and three cooling elements 2 connected to the power semiconductors, one for each power semiconductor 5. The power semiconductors form three identical power stages U, V, W. In the exemplary embodiment of FIG. 1, the power semiconductors 5 as well as the cooling elements 2 are disposed around a center axis 9 of the arrangement in such a manner that cooling surfaces 8 of the cooling elements 2 extend from the connections between the power semiconductors 5 and the cooling elements 2 substantially towards the center axis 9. In addition, in the exemplary embodiment of FIG. 1, the power semiconductors 5 extend from the connections between the power semiconductors 5 and the cooling elements 2 substantially away from the center axis 9 in such a manner that a channel 10 is demarked around the center axis from at least three sides, in which channel 10 the cooling surfaces 8 of the cooling elements are located and in which the cooling medium is able to flow in the direction of the center axis 9. The cooling medium can be, for example, dirty air or a liquid. The power semiconductors 5 and related printed circuit boards are in a clean room between the inner surface of a first ring film capacitor 11 and the cooling elements 2.

In the exemplary arrangement of FIG. 1, the channel 10 is demarked around the center axis 9. The cooling elements 2 and the power semiconductors 5 are fitted inside a tube-shaped ring film capacitor 11 having a circular cross-section. The ring film capacitor 11 does not necessarily have to be round, in the direction of the center axis 9, and for example a tube having a cross-section of a round-edged triangle or a square could also be used. The ring film capacitor 11 includes a roll of conducting and isolating material. The ring film capacitor 11 has a certain capacitance which depends on, for example, the number of turns in the roll, isolator's thickness and height of the roll. Current and voltage handling capacity can be enhanced by using a thicker conductor and isolator, respectively.

In accordance with an exemplary embodiment, two capacitors are used, and a second ring film capacitor 12 has the same shape as the first ring film capacitor 11 but a different physical size so that the first ring film capacitor 11 fits inside the second ring film capacitor 12. Therefore, the first ring film capacitor 11 has a smaller diameter and it may, for example, have more turns than the second ring film capacitor 12 to match the capacitance of the second ring film capacitor 12. The capacitors 11, 12 are connected in series by connecting one terminal of each of the capacitors 11, 12 together. This connection also generates a neutral point at the connected terminals. In accordance with an exemplary embodiment, one or both of the capacitors includes a cooling element, for example, a cooling fin or a set of cooling fins, which can be fixed to the neutral point.

The series-connected ring film capacitors 11, 12 function as a DC capacitor of the inverter arrangement. A separate clamp capacitor can be omitted from the inverter arrangement because the DC capacitor is so close to the power semiconductors 5. The construction of the arrangement also offers many other benefits. A high capacitance can be achieved with a simple arrangement of the two ring capacitors 11, 12. The capacitors do not block the channel 10 which is used for cooling the power semiconductors 5, and cooling of the capacitors can still be easily realized. The channel 10 can also be easily modified for water cooling purposes. A system with very low inductance can be arranged with the inverter arrangement by using ring film capacitors having a short length. The inverter arrangement is also easily scalable for higher power levels by making the capacitors longer, thicker, and/or increasing the number of turns in the capacitor.

In accordance with an exemplary embodiment, the power semiconductors 5, or groups of power semiconductors, can be installed to the inverter arrangement in a modular fashion, so that they can be removed and replaced one by one in case of a breakdown. For example, each power semiconductor 5 can be fixed to a separate cooling element 2, so that in case of a breakdown the broken power semiconductor can be removed with its associated cooling element, while the other power semiconductors and cooling elements remain in their place. The pairs of power semiconductors 5 and cooling elements 2 can be installed, for example, with the help of guides and slots or on rails, or they can be fastened to the inverter device without being fastened to each other, for example.

The inverter arrangement can include at least one choke. The at least one choke can be mounted on a top or bottom surface of the cooling elements. The at least one choke can be an air-core choke, for example. Further, the at least one choke can be an input choke and/or an output choke.

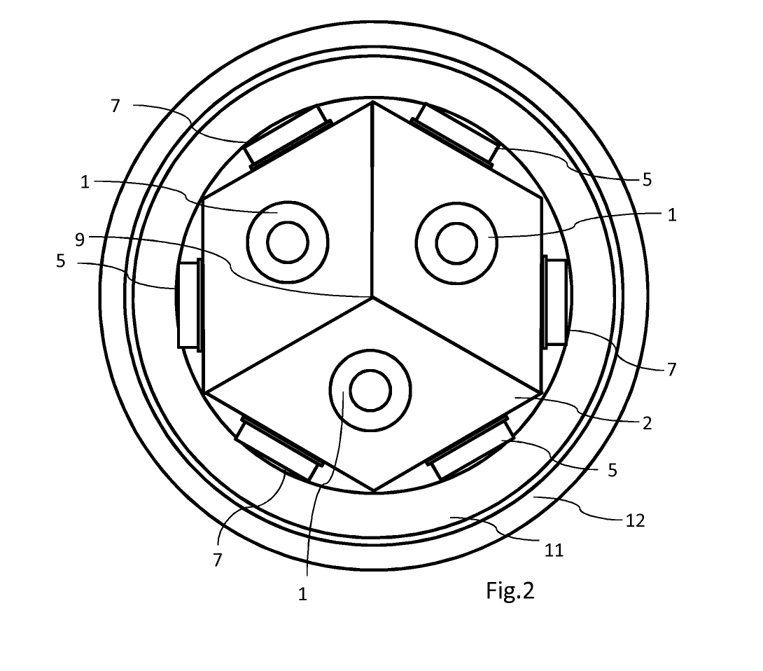

The arrangement of the exemplary embodiment shown in FIG. 2 includes six power semiconductors 5, 7, or six power semiconductor groups, and three cooling elements 2. The cooling elements 2 include plate-like and/or fin-like cooling surfaces similar to the cooling surfaces 8 of FIG. 1, even though the cooling surfaces are not illustrated in FIG. 2. The cooling elements 2 demark a channel 10 in which a cooling medium is able to flow in the direction of the center axis 9. The cooling medium can be, for example, dirty air or a liquid. The power semiconductors and related printed circuit boards are in a clean room between an inner surface of a first ring film capacitor 11 and the cooling elements 2.

The exemplary arrangement of FIG. 2 can be used as an inverter unit with a first set of power semiconductors 5 and as an inverter supply unit with a second set of power semiconductors 7. The inverter arrangement can include at least one choke 1. The at least one choke 1 can be mounted on a top or a bottom surface of the cooling elements. The at least one choke can be an air-core choke, for example. Further, the at least one choke 1 can be an input choke and/or an output choke. Aluminium or copper cooling elements 2, for example, do not react much to the magnetic flux of the choke 1. Thus, the support structures and outer casings of the cooling elements 2 are as far from the choke 1 as possible, so that the magnetic flux caused by the choke 1 cannot disturb external devices or the inverter's own electronics. In addition, possible heating in the support structures, caused by the magnetic flux, is taken care of by the cooling medium flow directly or indirectly via the cooling elements 2.

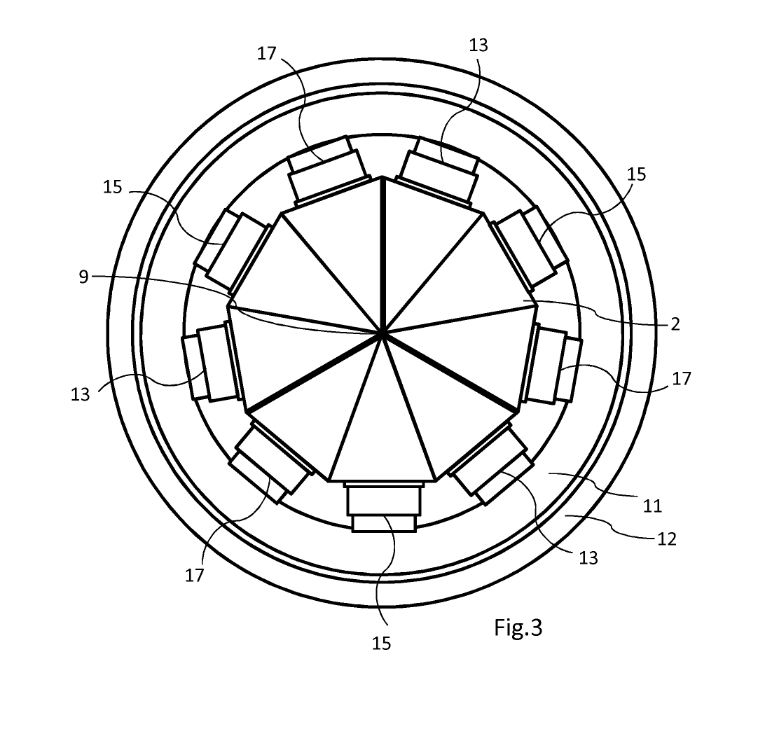

FIG. 3 shows a top view of an exemplary embodiment of an arrangement of a three-level inverter. The arrangement of the exemplary embodiment in FIG. 3 includes nine power semiconductors 13, 15, 17, or nine groups of power semiconductors 13, 15, 17, and nine cooling elements 2. The power semiconductors form three identical power stages U, V, W. In accordance with an exemplary embodiment, the middle power semiconductor 15 of each power stage is upside down compared to the other power semiconductors 13, 17, thus enabling short output wiring. The cooling elements 2 include plate-like or fin-like cooling surfaces similar to the cooling surfaces 8 of FIG. 1 even though the cooling surfaces are not illustrated in FIG. 3. The cooling elements 2 demark a channel 10 in which a cooling medium is able to flow in the direction of the center axis 9. The cooling medium can be, for example, dirty air or a liquid. The power semiconductors and related printed circuit boards are in a clean room between an inner surface of a first ring film capacitor 11 and the cooling elements 2. The inverter arrangement can include at least one choke. The at least one choke can be mounted on a top or a bottom surface of the cooling elements. The at least one choke can be an air-core choke, for example. Further, the at least one choke can be an input choke and/or an output choke.

It is to be further noted that, for the sake of clarity, many parts possibly present in the device utilizing the disclosure have been omitted from the drawings associated with the above examples. The mechanical attachment of the structure is shown in a much reduced manner in the drawings. For the sake of simplicity, the mechanical and electrical connections of the semiconductor modules 5, 7, 13, 15, 17 to each other and the electrical connections of the modules to, for example, chokes 1 and user interfaces, implementable in several alternative ways, have been omitted from the drawings.

Within the exemplary embodiments described above or in addition to them, the structure according to the present disclosure can be used in a plurality of additional embodiments. The structure according to the present disclosure can be utilized for implementing the basic structure of an inverter, rectifier or frequency converter, for example.

When utilized in connection with various electrical components, the mechanical structure according to the present disclosure works optimally in a lot wider area than present structures. Owing to this, the structure according to the present disclosure enables implementation of modularity through the whole device/series of devices, such as a frequency converter, involving not only one device but also its internal structures (e.g., power unit, choke unit, blower unit, control unit). Modularity in this sense can be considered to refer to standardizing the attachment points of each internal unit. The overall advantages obtained in this way for the manufacture can be significant.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

What is claimed is:

1. An arrangement for a modular inverter, the arrangement comprising:
a plurality of power semiconductors and cooling elements, the cooling elements being connected to the power semiconductors for cooling the power semiconductors, and the cooling elements each respectively having cooling surfaces,
wherein the power semiconductors and the cooling elements are disposed around a center axis of the arrangement such that the power semiconductors and the cooling elements demark a channel around the center axis from at least three sides,
wherein the channel cooling surfaces of the cooling elements extend to the channel, and a cooling medium is able to flow in the direction of the center axis in the channel,
wherein the power semiconductors extend from connections between the power semiconductors and the cooling elements substantially away from the center axis, and
wherein the arrangement comprises a first tube-shaped ring film capacitor disposed around the center axis of the arrangement, the power semiconductors being arranged between the cooling elements and an inner surface of the first ring film capacitor.

2. An arrangement according to claim 1, wherein the power semiconductors are divided into three or more groups, each group having at least one cooling element associated therewith, respectively.

3. An arrangement according to claim 1, comprising:
at least one choke disposed in the channel demarked around the center axis.

4. An arrangement according to claim 3, wherein the at least one choke is an air-core choke.

5. An arrangement according to claim 3, wherein the at least one choke is at least one of an input choke and an output choke.

6. An arrangement according to claim 1, wherein each of the power semiconductors is in connection with a single cooling element and is configured to be removed and replaced together with the single cooling element without removing any other cooling elements.

7. An arrangement according to claim 1, comprising:
a blower configured to blow dirty air into the channel to cool down the cooling elements and the power semiconductors.

8. An arrangement according to claim 1, comprising:
a second tube-shaped ring film capacitor around the first ring film capacitor.

9. An arrangement according to claim 8, wherein a terminal of the first ring film capacitor is connected to a terminal of the second ring film capacitor such that the connection of the connected terminals generates a neutral point at the connected terminals.

10. A motor controller comprising an arrangement according to claim 1.

11. A motor controller according to claim 10, wherein the motor controller is one of an inverter, a rectifier and a frequency converter.

12. A motor controller comprising an arrangement according to claim 2.

13. A motor controller comprising an arrangement according to claim 3.

14. A motor controller comprising an arrangement according to claim 4.

15. A motor controller comprising an arrangement according to claim 5.

16. A motor controller comprising an arrangement according to claim 6.

17. A motor controller comprising an arrangement according to claim 7.

18. A motor controller comprising an arrangement according to claim 8.

19. A motor controller comprising an arrangement according to claim 9.
